(19) United States
(12) Patent Application Publication
(10) Pub. No.: US 2024/0379622 A1
(43) Pub. Date: Nov. 14, 2024

(54) SEMICONDUCTOR PACKAGE

(71) Applicant: SAMSUNG ELECTRONICS CO., LTD., Suwon-si (KR)

(72) Inventors: Sung Yun WOO, Suwon-si (KR); Ji Min Choi, Suwon-si (KR); Joong Won Shin, Suwon-si (KR); Yeon Jin Lee, Suwon-si (KR); Jong Min Lee, Suwon-si (KR)

(73) Assignee: SAMSUNG ELECTRONICS CO., LTD., Suwon-si (KR)

(21) Appl. No.: 18/531,140

(22) Filed: Dec. 6, 2023

(30) Foreign Application Priority Data
May 9, 2023 (KR) 10-2023-0059960

(51) Int. Cl. H01L 25/065; H01L 23/00; H01L 23/31; H01L 23/48

(52) U.S. Cl. CPC H01L 25/0657; H01L 23/3157; H01L 23/481; H01L 24/08; H01L 24/16; H01L 24/32; H01L 24/73; H01L 2224/08145; H01L 2224/16145; H01L 2224/32145; H01L 2224/73204

(57) ABSTRACT

A semiconductor package includes a base chip including a top surface extending in a first horizontal direction and a second horizontal direction intersecting the first horizontal direction, a semiconductor chip stack including a first semiconductor chip and a second semiconductor chip which are sequentially stacked on the base chip in a vertical direction and are aligned on respective sides in the vertical direction, first through vias penetrating the base chip and spaced apart from each other in the first horizontal direction, second through vias penetrating the first semiconductor chip and spaced apart from each other in the first horizontal direction, third through vias penetrating the second semiconductor chip and spaced apart from each other in the first horizontal direction, first connection pads contacting the first through vias, second connection pads contacting the second through vias, and third connection pads contacting the third through vias.

### CROSS-REFERENCE TO RELATED APPLICATION

This application is based on and claims priority to Korean Patent Application No. 10-2023-0059960, filed on May 9, 2023, in the Korean Intellectual Property Office, the disclosure of which is incorporated by reference herein in its entirety.

### BACKGROUND

### 1. Field

Example embodiments of the present disclosure relate to a semiconductor package. cl 2. Description of Related Art

Semiconductor packages are increasingly developed to meet requirements such as multiple functionality, high capacity, compactness, and small size. As high-performance devices are increasingly being required, the size of semiconductor chips as well as the size of semiconductor packages are increasing accordingly. On the contrary, as electronic devices have become slimmer, the thickness of semiconductor packages has decreased.

Semiconductor packages are increasingly developed to meet requirements such as multiple functionality, high capacity, compactness, and small size. To this end, a technique has been suggested in which multiple semiconductor chips are integrated into a single semiconductor package to considerably reduce the size of the semiconductor package and to allow the semiconductor package to provide high capacity and multifunctionality.

### SUMMARY

One or more example embodiments provide a semiconductor package in which semiconductor devices and circuits may be efficiently arranged by forming through vias, penetrating semiconductor chips, to be not aligned with (offset from) one another.

Additional aspects will be set forth in part in the description which follows and, in part, will be apparent from the description, or may be learned by practice of the presented embodiments.

According to an aspect of an example embodiment, a semiconductor package may include a base chip including a top surface extending in a first horizontal direction and a second horizontal direction intersecting the first horizontal direction, a semiconductor chip stack including a first semiconductor chip and a second semiconductor chip which are sequentially stacked on the base chip in a vertical direction and are aligned on respective sides in the vertical direction, first through vias penetrating the base chip and spaced apart from each other in the first horizontal direction, second through vias penetrating the first semiconductor chip and spaced apart from each other in the first horizontal direction, third through vias penetrating the second semiconductor chip and spaced apart from each other in the first horizontal direction, first connection pads contacting the first through vias, second connection pads contacting the second through vias, and third connection pads contacting the third through vias, where at least one of the first through vias is offset from at least one of the second through vias in the vertical direction, at least one of the first through vias is aligned with at least one of the second through vias in the vertical direction, at least one of the second through vias is offset from at least one of the third through vias in the vertical direction, and at least one of the second through vias is aligned with at least one of the third through vias in the vertical direction.

According to an aspect of an example embodiment, a semiconductor package may include a base chip including a top surface extending in a first horizontal direction a second horizontal direction intersecting the first horizontal direction, a semiconductor chip stack including semiconductor chips, which are sequentially stacked on the base chip in a vertical direction and are aligned on respective sides in the vertical direction, first through vias extending into the base chip and spaced apart from each other in the first horizontal direction, second through vias extending into the semiconductor chip stack and spaced apart from each other in the first horizontal direction, first connection pads contacting the first through vias and second connection pads contacting the second through vias, where a first distance, in the first horizontal direction, between the first through vias is different from a second distance, in the first horizontal direction, between the second through vias and a third distance, in the first horizontal direction, between the first connection pads is different from a fourth distance, in the first horizontal direction, between the second connection pads.

According to an aspect of an example embodiment, a semiconductor package may include a base chip including top surface extending in a first horizontal direction and a second horizontal direction intersecting the first horizontal direction, a semiconductor chip stack including a first semiconductor chip and a second semiconductor chip which are sequentially stacked on the base chip in a vertical direction and are aligned on respective sides in the vertical direction, first through vias penetrating the base chip and spaced apart from each other in the first horizontal direction, second through vias penetrating the first semiconductor chip and spaced apart from each other in the first horizontal direction, third through vias penetrating the second semiconductor chip and spaced apart from each other in the first horizontal direction, a connection structure including first connection pads between the base chip and the first semiconductor chip and second connection pads between the first semiconductor chip and the second semiconductor chip, a mold layer at least partially covering the semiconductor chip stack on the top surface of the base chip and underfill material layers between the mold layer and between the first semiconductor chip and the second semiconductor chip, where at least one of the first through vias is offset from at least one of the second through vias in the vertical direction and at least one of the second through vias is offset from at least one of the third through vias in the vertical direction.

### BRIEF DESCRIPTION OF DRAWINGS

The above and other aspects and features of the present disclosure will become more apparent by describing in detail example embodiments thereof with reference to the attached drawings, in which:

FIG. 1 is a plan view of a semiconductor package according to one or more embodiments of the present disclosure;

FIGS. 2 through 8 are cross-sectional views taken along lines I-I′ of FIG. 1 according to embodiments of the present disclosure;

FIG. 9 is a plan view of a semiconductor package according to one or more embodiments of the present disclosure; and

FIG. 10 is a cross-sectional view taken along line II-II′ of FIG. 9 according to one or more embodiments of the present disclosure.

### DETAILED DESCRIPTION

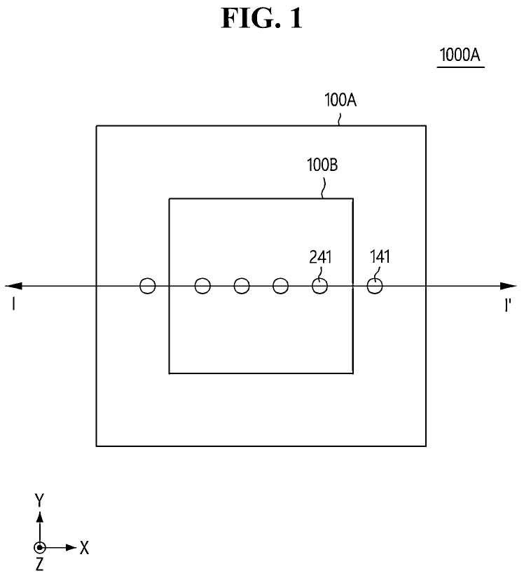

A semiconductor package according to some embodiments of the present disclosure will be described with reference to FIGS. 1 through 8.

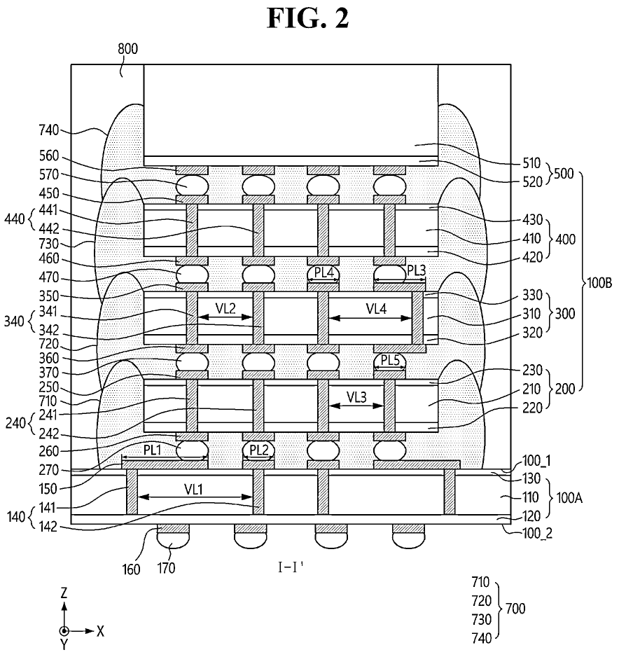

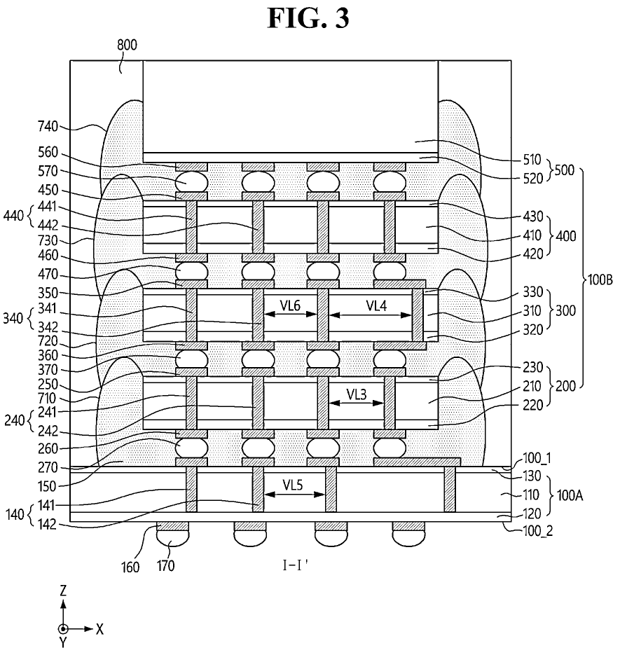

FIG. 1 is a plan view of a semiconductor package according to one or more embodiments of the present disclosure. FIGS. 2 through 8 are cross-sectional views taken along lines I-I′ of FIG. 1. In particular, FIGS. 2 through 8 show various example embodiments in cross-sectional view taken along lines I-I′ of FIG. 1. For convenience, the embodiments of FIGS. 3 through 8 will be described, focusing mainly on the differences with the embodiments of FIGS. 1 and 2, and repeated descriptions may be omitted.

Referring to FIGS. 1 and 2, a semiconductor package 1000A may include a base chip 100A, a semiconductor chip stack 100B, a plurality of through vias 140, 240, 340, and 440, a plurality of upper connection pads 150, 250, 350, and 450, a plurality of lower connection pads 160, 260, 360, 460, and 560, a plurality of connection terminals 170, 270, 370, 470, and 570, an underfill material layer 700, and a mold layer 800. First, second, third, and fourth semiconductor chips 200, 300, 400, and 500, which are stacked on the base chip 100A, may be electrically connected to one another via the through vias 140, 240, 340, and 440.

The base chip 100A may include a base substrate 110, a base circuit layer 120, and a base insulating layer 130.

The base chip 100A may have top and bottom surfaces 100_1 and 100_2, which are opposite to each other. The top surface 100_1 of the base chip 100A may be defined by the base insulating layer 130, and the bottom surface 100_2 may be defined by the base circuit layer 120. The upper and bottom surfaces 100_1 and 100_2 of the base chip 100A may extend in first and second horizontal directions X and Y. For example, the first and second horizontal directions X and Y may intersect each other at a right angle.

The base chip 100A may be, for example, a buffer chip having a plurality of logic devices and/or memory devices on the base circuit layer 120. Thus, the base chip 100A may transmit signals from the semiconductor chip stack 100B, which is stacked on the base chip 100A, to the outside and may transmit signals and power from the outside to the semiconductor chip stack 100B. The base chip 100A may perform a logic function and/or a memory function via the logic devices and/or the memory devices, but embodiments of the present disclosure are not limited thereto. Alternatively, the base chip 100A may include only the logic devices and may thus perform only the logic function.

The base substrate 110 may be formed of a semiconductor material such as silicon (Si). Alternatively, in some embodiments, the base substrate 110 may be a printed circuit board (PCB) not including a semiconductor material or a glass substrate, and in such a case, the base chip 100A may not include a device layer or through vias.

The base substrate 110 may include, for example, a semiconductor element such as Si or germanium (Ge), or a compound semiconductor such as silicon carbide (SiC), gallium arsenide (GaAs), indium arsenide (InAs), or indium phosphide (InP). The base substrate 110 may have a silicon-on-insulator (SOI) structure. The base substrate 110 may include conductive regions (e.g., wells or structures doped with impurities). The base substrate 110 may include various device isolation structures such as shallow trench isolations (STIs).

The base circuit layer 120 may be disposed on the bottom surface of the base substrate 110 and may include various devices. For example, the devices of the base circuit layer 120 may include a variety of active devices and/or passive devices such as field-effect transistors (FETs) (e.g., planar FETs or fin-shaped FETs (FinFETs)), memory devices such as flash memories, dynamic random-access memories (DRAMs), static RAMs (SRAMs), electrically erasable programmable read-only memories (ROMs) (EEPROMs), phase-change RAMS (PRAMs), a magnetoresistive RAMs (MRAMs), ferroelectric RAMs (FeRAMs), resistive RAMs (RRAMs), logic devices such as AND, OR, and NOT logic devices, system large-scale integration (LSI) devices, complementary metal-oxide-semiconductor (CMOS) imaging sensors (CISs), or micro-electro-mechanical systems (MEMSs).

The base circuit layer 120 may further include an interlayer insulating layer and a multilayer wiring layer. The interlayer insulating layer may include silicon oxide or silicon nitride. The multilayer wiring layer may include multilayer wires and/or vertical contacts. The multilayer wiring layer may connect the devices of the base circuit layer 120 to one another, to the conductive regions of the base substrate 110, or to outer connection terminals 170.

The base insulating layer 130 may be formed on the top surface 100_1 of the base substrate 110 and may protect the base substrate 110. The base insulating layer 130 may include an insulating material. The base insulating layer 130 may be formed of silicon oxide, silicon nitride, and silicon oxynitride, but the material of the base insulating layer 130 is not particularly limited. That is, alternatively, the base insulating layer 130 may be formed of a polymer such as polyimide (PI). A lower insulating layer may be further formed on the bottom surface of the base circuit layer 120.

Upper connection pads 150 may be disposed on the base insulating layer 130. The upper connection pads 150 may include at least one of, for example, aluminum (Al), copper (Cu), nickel (Ni), tungsten (W), platinum (Pt), and gold (Au). Lower connection pads 160 may be disposed below the base circuit layer 120 and may include a material similar to that of the upper connection pads 150. However, the materials of the upper connection pads 150 and the lower connection pads 160 are not particularly limited.

The outer connection terminals 170 may be disposed on the lower connection pads 160 and may be connected to the wiring layer of the base circuit layer 120 or to base chip through vias 140. The semiconductor package 1000A may be mounted on an outer substrate, such as an interposer or a package substrate, through the outer connection terminals 170.

Outer connection terminals 170 may be formed as solder balls. Alternatively, in some embodiments, the outer connection terminals 170 may include both pillars and solder. The pillars may have a cylindrical shape or a polygonal pillar shape such as a square or octagonal pillar shape and may include, for example, Ni, Cu, palladium (Pd), Pt, Au, or a combination thereof. The solder has a spherical or ball shape and may include, for example, tin (Sn), indium (In), bismuth (Bi), antimony (Sb), copper (Cu), silver (Ag), zinc (Zn), lead (Pb) and/or an alloy thereof.

Base chip through vias 140 may extend into the base chip 100A in a vertical direction Z. The base chip through vias 140 may penetrate the base substrate 110 in the vertical direction Z and may provide electrical paths for connecting the upper connection pads 150 and the lower connection pads 160. The base chip through vias 140 may include first base chip through vias 141 and second base chip through vias 142, which are spaced apart from the first base chip through vias 141 in the first horizontal direction X.

The base chip through vias 140 may include conductive plugs and barrier films surrounding the conductive plugs. The conductive plugs may include a metal material such as W, titanium (Ti), Al, or Cu. The conductive plugs may be formed by a plating process, a physical vapor deposition (PVD) process, or a chemical vapor deposition (CVD) process. The barrier films may include insulating barrier films and/or conductive barrier films. The insulating barrier films may be formed of an oxide, a nitride, a carbide, a polymer, or a combination thereof. The conductive barrier films may be disposed between the insulating barrier films and the conductive plugs. The conductive barrier layers may include, for example, a metal compound such as tungsten nitride (WN), titanium nitride (TiN), or tantalum nitride (TaN). The barrier films may be formed by a PVD process or a CVD process.

The semiconductor chip stack 100B may include the first, second, third, and fourth semiconductor chips 200, 300, 400, and 500. First sides of the first, second, third, and fourth semiconductor chips 200, 300, 400, and 500 may be aligned with one another in the vertical direction Z. Second sides of the first, second, third, and fourth semiconductor chips 200, 300, 400, and 500 that are opposite to the first sides may be aligned with one another in the vertical direction Z.

The first, second, third, and fourth semiconductor chips 200, 300, 400, and 500 may include semiconductor memory chips. The semiconductor memory chips may be volatile semiconductor memory chips such as DRAMs or SRAMs or nonvolatile semiconductor memory chips such as PRAMs, MRAMs, FeRAMs, or RRAMs.

In some embodiments, the base chip 100A may be a semiconductor logic chip, and the first, second, third, and fourth semiconductor chips 200, 300, 400, and 500 may be semiconductor memory chips. In other embodiments, the base chip 100A may be a controller semiconductor chip controlling input/output operations of each of the first, second, third, and fourth semiconductor chips 200, 300, 400, and 500, which are electrically connected to the base chip 100A.

FIG. 2 illustrates that a total of four semiconductor chips are stacked, but embodiments of the present disclosure are not limited thereto. Alternatively, a total of eight semiconductor chips or various numbers of semiconductor chips may be stacked.

The first semiconductor chip 200 may include a first semiconductor substrate 210, a first semiconductor chip circuit layer 220, and a first semiconductor chip insulating layer 230. The first semiconductor substrate 210 may have a similar characteristic to that of the base substrate 110 of the base chip 100A.

The first semiconductor chip circuit layer 220 may be disposed on the bottom surface of the first semiconductor substrate 210 and may include a plurality of memory devices. For example, the first semiconductor chip circuit layer 220 may include volatile memory devices such as DRAMs or SRAMs or nonvolatile memory devices such as PRAMs, MRAMs, FeRAMs, or RRAMs. For example, the first semiconductor chip 200 may include DRAMs.

Accordingly, the semiconductor package 1000A may be used in a high-bandwidth memory (HBM) product or an electronic data processing (EDP) product.

The first semiconductor chip circuit layer 220 may include a multilayer wiring layer. The multilayer wiring layer of the first semiconductor chip circuit layer 220 may have a similar characteristic to that of the multilayer wiring layer of the base circuit layer 120. Accordingly, the devices of the first semiconductor chip circuit layer 220 may be electrically connected to first semiconductor chip connection terminals 270 via the multilayer wiring layer of the first semiconductor chip circuit layer 220.

The first semiconductor chip insulating layer 230 may be formed on the top surface of the first semiconductor substrate 210 and may protect the first semiconductor substrate 210. The first semiconductor chip insulating layer 230 may have a similar characteristic to that of the base insulating layer 130 of the base chip 100A.

Upper connection pads 250 and lower connection pads 260 of the first semiconductor chip 200 may be formed on the top surface of the first semiconductor chip insulating layer 230 and the bottom surface of the first semiconductor chip circuit layer 220, respectively. The upper connection pads 250 and lower connection pads 260 of the first semiconductor chip 200 may have similar characteristics to those of the upper connection pads 150 and the lower connection pads 160, respectively, of the base chip 100A.

The first semiconductor chip connection terminals 270 may be disposed on the lower connection pads 260 of the first semiconductor chip 200 and may be connected to the wiring layer of the first semiconductor chip circuit layer 220 or to the first semiconductor chip through vias 240. The first semiconductor chip connection terminals 270 may have a similar characteristic to that of the outer connection terminals 170.

The first semiconductor chip through vias 240 may extend into the first semiconductor chip 200 in the vertical direction Z. The first semiconductor chip through vias 240 may penetrate the first semiconductor substrate 210, the first semiconductor chip circuit layer 220, and the first semiconductor chip insulating layer 230 in the vertical direction Z. The first semiconductor chip through vias 240 may provide electrical paths for connecting the upper connection pads 250 and the lower connection pads 260. The first semiconductor chip through vias 240 may include (1_1)-th semiconductor chip through vias 241 and (1_2)-th semiconductor chip through vias 242, which are spaced apart from the (1_1)-th semiconductor chip through vias 241 in the first horizontal direction X (one semiconductor chip through via 241 and one semiconductor through chip via 242 are identified for convenience of illustration). The first semiconductor chip through vias 240 may include conductive plugs and barrier films surrounding the conductive plugs. The first semiconductor chip through vias 240 may have a similar characteristic to that of the base chip through vias 140.

The second semiconductor chip 300 may include a second semiconductor substrate 310, a second semiconductor chip circuit layer 320, and a second semiconductor chip insulating layer 330. The second semiconductor substrate 310 may have a similar characteristic to that of the first semiconductor substrate 210 of the first semiconductor chip 200.

The second semiconductor chip circuit layer 320 may be disposed on the bottom surface of the second semiconductor substrate 310 and may include a plurality of memory devices. For example, the second semiconductor chip circuit layer 320 may include volatile memory devices such as DRAMs or SRAMs or nonvolatile memory devices such as PRAMs, MRAMs, FeRAMs, or RRAMs. For example, the second semiconductor chip 300 may include DRAMs. Accordingly, the semiconductor package 1000A may be used in an HBM product or an EDP product.

The second semiconductor chip circuit layer 320 may include a multilayer wiring layer. The multilayer wiring layer of the second semiconductor chip circuit layer 320 may have a similar characteristic to that of the multilayer wiring layer of the first semiconductor chip circuit layer 220. Accordingly, the devices of the second semiconductor chip circuit layer 320 may be electrically connected to second semiconductor chip connection terminals 370 via the multilayer wiring layer of the second semiconductor chip circuit layer 320.

The second semiconductor chip insulating layer 330 may be formed on the top surface of the second semiconductor substrate 310 and may protect the second semiconductor substrate 310. The second semiconductor chip insulating layer 330 may have a similar characteristic to that of the first semiconductor chip insulating layer 230.

Upper connection pads 350 and lower connection pads 360 of the second semiconductor chip 300 may be formed on the top surface of the second semiconductor chip insulating layer 330 and the bottom surface of the second semiconductor chip circuit layer 320, respectively. The upper connection pads 350 and the lower connection pads 360 of the second semiconductor chip 300 may have similar characteristics to those of the upper connection pads 250 and the lower connection pads 260, respectively, of the first semiconductor chip 200.

The second semiconductor chip connection terminals 370 may be disposed on the lower connection pads 360 of the second semiconductor chip 300 and may be connected to the wiring layer of the second semiconductor chip circuit layer 320 or to second semiconductor chip through vias 340. The second semiconductor chip connection terminals 370 may have a similar characteristic to that of the first semiconductor chip connection terminals 270.

The second semiconductor chip through vias 340 may extend into the second semiconductor chip 300 in the vertical direction Z. The second semiconductor chip through vias 340 may penetrate the second semiconductor substrate 310, the second semiconductor chip circuit layer 320, and the second semiconductor chip insulating layer 330 in the vertical direction Z. The second semiconductor chip through vias 340 may provide electrical paths for connecting the upper connection pads 350 and the lower connection pads 360. The second semiconductor chip through vias 340 may include (2_1)-th semiconductor chip through vias 341 and (2_2)-th semiconductor chip through vias 342, which are spaced apart from the (2_1)-th semiconductor chip through vias 341 in the first horizontal direction X (one via 341 and one via 342 are identified for convenience of illustration). The second semiconductor chip through vias 340 may include conductive plugs and barrier films surrounding the conductive plugs. The second semiconductor chip through vias 340 may have a similar characteristic to that of the first semiconductor chip through vias 240.

The third semiconductor chip 400 may include a third semiconductor substrate 410, a third semiconductor chip circuit layer 420, and a third semiconductor chip insulating layer 430. The third semiconductor substrate 410 may have a similar characteristic to that of the first semiconductor substrate 210 of the first semiconductor chip 200.

The third semiconductor chip circuit layer 420 may be disposed on the bottom surface of the third semiconductor substrate 410 and may include a plurality of memory devices. For example, the third semiconductor chip circuit layer 420 may include volatile memory devices such as DRAMs or SRAMs or nonvolatile memory devices such as PRAMs, MRAMs, FeRAMs, or RRAMs. For example, the third semiconductor chip 400 may include DRAMs. Accordingly, the semiconductor package 1000A may be used in an HBM product or an EDP product.

The third semiconductor chip circuit layer 420 may include a multilayer wiring layer. The multilayer wiring layer of the third semiconductor chip circuit layer 420 may have a similar characteristic to that of the multilayer wiring layer of the first semiconductor chip circuit layer 220. Accordingly, the devices of the third semiconductor chip circuit layer 420 may be electrically connected to third semiconductor chip connection terminals 470 via the multilayer wiring layer of the third semiconductor chip circuit layer 420.

The third semiconductor chip insulating layer 430 may be formed on the top surface of the third semiconductor substrate 410 and may protect the third semiconductor substrate 410. The third semiconductor chip insulating layer 430 may have a similar characteristic to that of the first semiconductor chip insulating layer 230.

Upper connection pads 450 and lower connection pads 460 of the third semiconductor chip 400 may be formed on the top surface of the third semiconductor chip insulating layer 430 and the bottom surface of the third semiconductor chip circuit layer 420, respectively. The upper connection pads 450 and lower connection pads 460 of the third semiconductor chip 400 may have similar characteristics to those of the upper connection pads 250 and the lower connection pads 260 of the first semiconductor chip 200.

The third semiconductor chip connection terminals 470 may be disposed on the lower connection pads 460 of the third semiconductor chip 400 and may be connected to the wiring layer of the third semiconductor chip circuit layer 420 or to third semiconductor chip through vias 440. The third semiconductor chip connection terminals 470 may have a similar characteristic to that of the first semiconductor chip connection terminals 270.

The third semiconductor chip through vias 440 may extend into the third semiconductor chip 400 in the vertical direction Z. The third semiconductor chip through vias 440 may penetrate the third semiconductor substrate 410, the third semiconductor chip circuit layer 420, and the third semiconductor chip insulating layer 430 in the vertical direction Z. The third semiconductor chip through vias 440 may provide electrical paths for connecting the upper connection pads 450 and the lower connection pads 460. The third semiconductor chip through vias 440 may include (3_1)-th semiconductor chip through vias 441 and (3_2)-th semiconductor chip through vias 442, which are spaced apart from the (3_1)-th semiconductor chip through vias 441 in the first horizontal direction X (one via 441 and one via 442 are identified for convenience of illustration). The third semiconductor chip through vias 440 may include conductive plugs and barrier films surrounding the conductive plugs. The third semiconductor chip through vias 440 may have a similar characteristic to that of the first semiconductor chip through vias 240.

The fourth semiconductor chip 500 may include a fourth semiconductor substrate 510 and a fourth semiconductor chip circuit layer 520. The fourth semiconductor substrate 510 may have a similar characteristic to that of the first semiconductor substrate 210 of the first semiconductor chip 200.

The fourth semiconductor chip circuit layer 520 may be disposed on the bottom surface of the fourth semiconductor substrate 510 and may include a plurality of memory devices. For example, the fourth semiconductor chip circuit layer 520 may include volatile memory devices such as DRAMs or SRAMs or nonvolatile memory devices such as PRAMs, MRAMs, FeRAMs, or RRAMs. For example, the fourth semiconductor chip 500 may include DRAMs. Accordingly, the semiconductor package 1000A may be used in an HBM product or an EDP product.

Although not specifically illustrated, the fourth semiconductor chip circuit layer 520 may include a multilayer wiring layer. The multilayer wiring layer of the fourth semiconductor chip circuit layer 520 may have a similar characteristic to that of the multilayer wiring layer of the first semiconductor chip circuit layer 220. Accordingly, the devices of the fourth semiconductor chip circuit layer 520 may be electrically connected to fourth semiconductor chip connection terminals 570 through the multilayer wiring layer of the fourth semiconductor chip circuit layer 520.

Lower connection pads 560 of the fourth semiconductor chip 500 may be formed on the bottom surface of the fourth semiconductor chip circuit layer 520. The lower connection pads 560 of the fourth semiconductor chip 500 may have a similar characteristic to that of the lower connection pads 260 of the first semiconductor chip 200.

The fourth semiconductor chip connection terminals 570 may be disposed on the lower connection pads 560 of the fourth semiconductor chip 500 and may be connected to the wiring layer of the fourth semiconductor chip circuit layer 520. The fourth semiconductor chip connection terminals 570 may have a similar characteristic to that of the first semiconductor chip connection terminals 270.

The fourth semiconductor chip 500, which is disposed at an uppermost part of the semiconductor chip stack 100B, may not include through vias. At least parts of the sides of the fourth semiconductor chip 500 may be covered or at least partially covered by the mold layer 800. The top surface of the fourth semiconductor chip 500 may be exposed from the mold layer 800. Alternatively, the top surface of the fourth semiconductor chip 500 may be covered or at least partially covered by the mold layer 800.

The underfill material layer 700 may be disposed between the mold layer 800 and the first, second, third, and fourth semiconductor chips 200, 300, 400, and 500. The underfill material layer 700 may be disposed below the each of the first, second, third, and fourth semiconductor chips 200, 300, 400, and 500, on the base chip 100A.

The underfill material layer 700 may include a first underfill material layer 710, which is disposed between the base chip 100A and the first semiconductor chip 200, a second underfill material layer 720, which is disposed between the first and second semiconductor chips 200 and 300, a third underfill material layer 730, which is disposed between the second and third semiconductor chips 300 and 400, and a fourth underfill material layer 740, which is disposed between the third and fourth semiconductor chips 400 and 500.

The first, second, third and fourth underfill material layers 710, 720, 730, and 740 may include the same material. The first, second, third, and fourth underfill material layers 710, 720, 730, and 740 may include, for example, non-conductive films (NCFs).

The first underfill material layer 710 may fill the gap between the top surface 100_1 of the base chip 100A and the first semiconductor chip 200 and may surround or at least partially surround the first semiconductor chip connection terminals 270. The first underfill material layer 710 may protrude laterally (i.e., in the first horizontal direction X and/or the second horizontal direction Y) from the sides of the first semiconductor chip 200 and may cover at least parts of the sides of the first semiconductor chip 200.

The second underfill material layer 720 may fill the gap between the top surface of the first semiconductor chip 200 and the second semiconductor chip 300 and may surround or at least partially surround the second semiconductor chip connection terminals 370. The second underfill material layer 720 may protrude laterally from the sides of each of the first and second semiconductor chip 200 and 300 and may cover at least parts of the sides of the second semiconductor chip 300.

The third underfill material layer 730 may fill the gap between the top surface of the second semiconductor chip 300 and the third semiconductor chip 400 and may surround or at least partially surround the third semiconductor chip connection terminals 470. The third underfill material layer 730 may protrude laterally from the sides of each of the second and third semiconductor chips 300 and 400 and may cover at least parts of the sides of the third semiconductor chip 400.

The fourth underfill material layer 740 may fill the gap between the top surface of the third semiconductor chip 400 and the fourth semiconductor chip 500 and may surround or at least partially surround the fourth semiconductor chip connection terminals 570. The fourth underfill material layer 740 may protrude laterally from the sides of each of the third and fourth semiconductor chips 400 and 500 and may cover at least parts of the sides of the fourth semiconductor chip 500.

The first, second, third, and fourth underfill material layers 710, 720, 730, and 740 may include an adhesive resin and flux. The adhesive resin may be, for example, a thermosetting resin. The adhesive resin may change from a gel state to a liquid state when subjected to heat and pressure and may then be cured. In general, in a semiconductor package manufacturing process, the sidewalls of the underfill material layer 700 may include curved surfaces. The flux may be used in soldering for electrically bonding the first, second, third, and fourth semiconductor chips 200, 300, 400, and 500 during the manufacture of the semiconductor package 1000A. The flux improves the spread and the wettability of solder, and the flux may be applied in advance to areas where the solder is to be applied or may be included in the underfill material layer 700. For example, the flux is classified into a resin-based, organic-based, and inorganic-based flux, and generally, the resin-based flux may be used in electronic devices.

The underfill material layer 700 may be used as an interlayer bonding material between the first, second, third, and fourth semiconductor chips 200, 300, 400, and 500.

The mold layer 800 may be disposed on the top surface 100_1 of the base chip 100A and may be formed to cover or at least partially cover the first, second, third, and fourth semiconductor chips 200, 300, 400, and 500. The mold layer 800 may surround or at least partially surround the first, second, third, and fourth semiconductor chips 200, 300, 400, and 500. Specifically, the mold layer 800 may cover at least parts of the sides of each of the first, second, third, and fourth semiconductor chips 200, 300, 400, and 500 and the first, second, third, and fourth underfill material layers 710, 720, 730, and 740. The mold layer 800 may include an insulating material such as, for example, an epoxy molding compound (EMC).

Referring to FIG. 2, at least one of the base chip through vias 140, which penetrate the base chip 110A, may be offset from (not aligned with) at least one of the first semiconductor chip through vias 240, which penetrate the first semiconductor chip 200, the second semiconductor chip through vias 340, which penetrate the second semiconductor chip 300, and the third semiconductor chip through vias 440, which penetrate the fourth semiconductor chip 400, in the vertical direction Z.

Specifically, the second base chip through vias 142, which are inner base chip through vias 140 penetrating the base chip 110A, may be aligned with the (2_2)-th semiconductor chip through vias 342, which are inner second semiconductor chip through vias 340 penetrating the second semiconductor chip 300, in the vertical direction Z, and the first base chip through vias 141, which are outermost base chip through vias 140 penetrating the base chip 110A, may be offset from the (2_1)-th semiconductor chip through vias 341, which are outermost second semiconductor chip through vias 340 penetrating the second semiconductor chip 300, in the vertical direction Z.

In this case, a distance VL1, in the first horizontal direction X, between the first base chip through vias 142 may differ from a distance VL2, in the first horizontal direction X, between the (2_1)-th semiconductor chip through vias 341 and the (2_2)-th semiconductor chip through vias 342.

The distance VL1 may be greater than the distance VL2, but embodiments of the present disclosure are not limited thereto. Alternatively, the distance VL1 may be less than the distance VL2.

The upper connection pads 150 of the base chip 100A may include upper connection pads 150 that contact the first base chip through vias 141 and upper connection pads 150 that contact the second base chip through vias 142. The upper connection pads 150 may protrude from the first semiconductor chip 200 in the first horizontal direction X.

For example, a length PL1, in the first horizontal direction X, of the upper connection pads 150 that contact the first base chip through vias 141 may differ from a length PL2, in the first horizontal direction X, of the upper connection pads 150 that contact the second base chip through vias 142. The length PL1 may be greater than the length PL2, but embodiments of the present disclosure are not limited thereto.

At least one of the first semiconductor chip through vias 240, which penetrate the first semiconductor chip 200, may be offset from at least one of the second semiconductor chip through vias 340, which penetrate the second semiconductor chip 300, in the vertical direction Z.

In this case, a distance VL3, in the first horizontal direction X, between the (1_1)-th semiconductor chip through vias 241, which are outermost first semiconductor chip through vias 240 penetrating the first semiconductor chip 200, and the (1_2)-th semiconductor chip through vias 242, which are inner first semiconductor chip through vias 240 penetrating the first semiconductor chip 200, may differ from a distance VL4, in the first horizontal direction X, between the (2_1)-th semiconductor chip through vias 341, which are outermost second semiconductor chip through vias 340 penetrating the second semiconductor chip 300, and the (2_2)-th semiconductor chip through vias 342, which are inner second semiconductor chip through vias 340 penetrating the second semiconductor chip 300.

The distance VL4 may be greater than the distance VL3, but embodiments of the present disclosure are not limited thereto. Alternatively, the distance VL4 may be less than the distance VL3.

The upper connection pads 350 of the second semiconductor chip 300 may include upper connection pads 350 that contact the outermost second semiconductor chip through vias 340 (i.e., the (2_1)-th semiconductor chip through vias 341 and upper connection pads 350 that contact the inner second semiconductor chip through vias 340, i.e., the (2_2)-th semiconductor chip through vias 342).

For example, a length PL3, in the first horizontal direction X, of the upper connection pads 350 that contact the (2_1)-th semiconductor chip through vias 341 may differ from a length PL4, in the first horizontal direction X, of the upper connection pads 350 that are in contact with the (2_2)-th semiconductor chip through vias 342.

The length PL3 may be greater than the length PL4, but embodiments of the present disclosure are not limited thereto. Alternatively, the length PL3 may be less than the length PL4.

The upper connection pads 250 of the first semiconductor chip 200 may include upper connection pads 250 that contact the outermost first semiconductor chip through vias 240 (i.e., the (1_1)-th semiconductor chip through vias 241, and upper connection pads 250 that contact the inner first semiconductor chip through vias 240, i.e., the (1_2)-th semiconductor chip through vias 242).

A length PL5, in the first horizontal direction X, of the upper connection pads 250 that contact the (1_1)-th semiconductor chip through vias 241 may differ from the length of the upper connection pads 350 that contact the (2_1)-th semiconductor chip through vias 341 (i.e., the length PL3). The length PL3 may be greater than the length P15, but embodiments of the present disclosure are not limited thereto.

In the semiconductor package 1000A of FIG. 2, at least some of the first through vias 140 may not be positioned within a horizontal width (a width in the X direction) the semiconductor chip stack 100B. The outermost first through vias 140 (i.e., the first base chip through vias 141) may be disposed on the outside of the semiconductor chip stack 100B in the first horizontal direction X and/or the second horizontal direction Y.

As groups of through vias penetrating semiconductor chips are formed to not be aligned with one another, semiconductor devices and circuits may be efficiently arranged. For example, the number and size of semiconductor devices to be disposed in each semiconductor chip may be varied from one semiconductor chip to another semiconductor chip.

Referring to FIG. 3, at least one of the inner base chip through vias 140 may be offset, in the vertical direction Z, from at least one of the inner first semiconductor chip through vias 240, the inner second semiconductor chip through vias 340, and inner third semiconductor chip through vias 440.

Specifically, at least one of the second base chip through vias 142 may be offset from at least one of the (2_2)-th semiconductor chip through vias 342.

In this case, a distance VL5, in the first horizontal direction X, between the second base chip through vias 142 may differ from a distance VL6, in the first horizontal direction X, between the (2_2)-th semiconductor chip through vias 342.

The distance VL5 may be greater than the distance VL6, but embodiments of the present disclosure are not limited thereto. Alternatively, the distance VL5 may be less than the distance VL6.

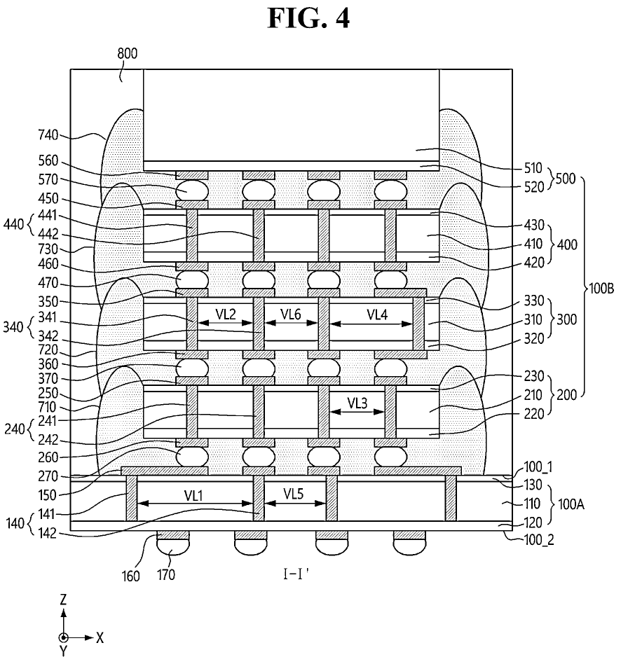

Referring to FIG. 4, at least one of the outermost base chip through vias 140 may be offset from at least one of the outermost first semiconductor chip through vias 240, the outermost second semiconductor chip through vias 340, and outermost third semiconductor chip through vias 440 in the vertical direction Z.

Also, at least one of the outermost base chip through vias 140 may be offset from at least one of the inner first semiconductor chip through vias 240, the inner second semiconductor chip through vias 340, and the inner third semiconductor chip through vias 440 in the vertical direction Z.

Also, at least one of the first semiconductor chip through vias 240 may be offset from at least one of the second semiconductor chip through vias 340 in the vertical direction Z.

In this case, the distance VL1 between the first base chip through vias 141 and the second base chip through vias 142 may differ from the distance VL2 between the (2_1)-th semiconductor chip through vias 341 and (2_2)-th semiconductor chip through vias 342. The distance VL1 may be greater than the distance VL2, but embodiments of the present disclosure are not limited thereto.

Also, the distance VL3 between the outermost first semiconductor chip through vias 240 (i.e., the (1_1)-th semiconductor chip through vias 241) and the inner first semiconductor chip through vias 240 (i.e., the (1_2)-th semiconductor chip through vias 242) may differ from the distance VL4 between the outermost second semiconductor chip through vias 340 (i.e., the (2_1)-th semiconductor chip through vias 341) and the inner second semiconductor chip through vias 340 (i.e., the (2_2)-th semiconductor chip through vias 342). The distance VL4 may be greater than the distance VL3, but embodiments of the present disclosure are not limited thereto.

Also, the distance VL5 between the inner base chip through vias 140 (i.e., the second base chip through vias 142) may differ from the distance VL6 between the inner second semiconductor chip through vias 340 (i.e., the (2_2)-th semiconductor chip through vias 342). The distance VL5 may be greater than the distance VL6, but embodiments of the present disclosure are not limited thereto.

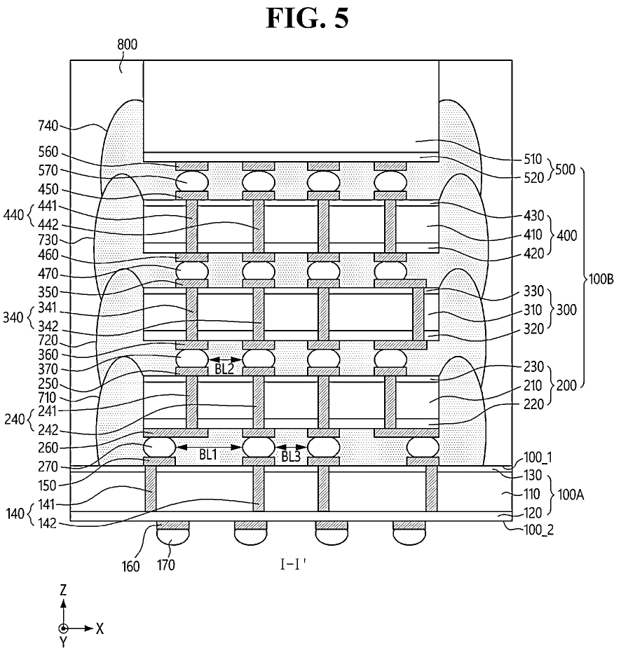

Referring to FIG. 5, at least two of the connection terminals 170, 270, 370, 470, and 570 may be not aligned with each other in the vertical direction Z.

In this case, the distances, in the first horizontal direction X, between the connection terminals 170, 270, 370, 470, and 570 may differ.

A distance BL1 between outermost first semiconductor chip connection terminals 270 and inner first semiconductor chip connection terminals 270 may differ from a distance BL2 between outermost second semiconductor chip connection terminals 370 and inner second semiconductor chip connection terminals 370.

The distance BL1 may be greater than the distance BL2, but embodiments of the present disclosure are not limited thereto. Alternatively, although not specifically illustrated, the distance BL1 may be less than the distance BL2.

Also, the distance BL1 may differ from a distance BL3 between the inner first semiconductor chip connection terminals 270. The distance BL1 may be greater than the distance BL3, but embodiments of the present disclosure are not limited thereto.

The distance BL3 may differ from the distance between the inner second semiconductor chip connection terminals 370.

In the semiconductor package 1000A of FIG. 5, unlike in the semiconductor package 1000A of FIG. 2, the first through vias 140 may all be positioned within a horizontal width (an X direction width) of the semiconductor chip stack 100B.

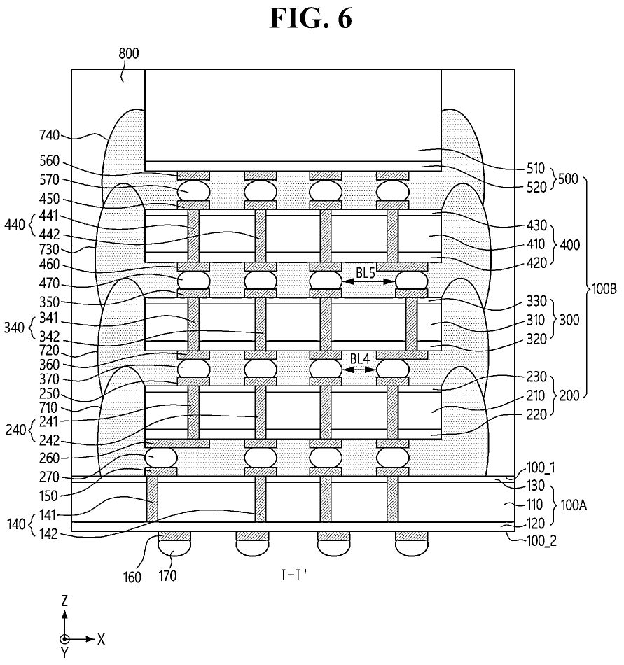

Referring to FIG. 6, a distance BL4 between the outermost second semiconductor chip connection terminals 370 and the inner second semiconductor chip connection terminals 370 may differ from a distance BL5 between outermost third semiconductor chip connection terminals 470 and inner third semiconductor chip connection terminals 470.

The distance BL5 may be greater than the distance BL4, but embodiments of the present disclosure are not limited thereto. Alternatively, the distance BL5 may be less than the distance BL4.

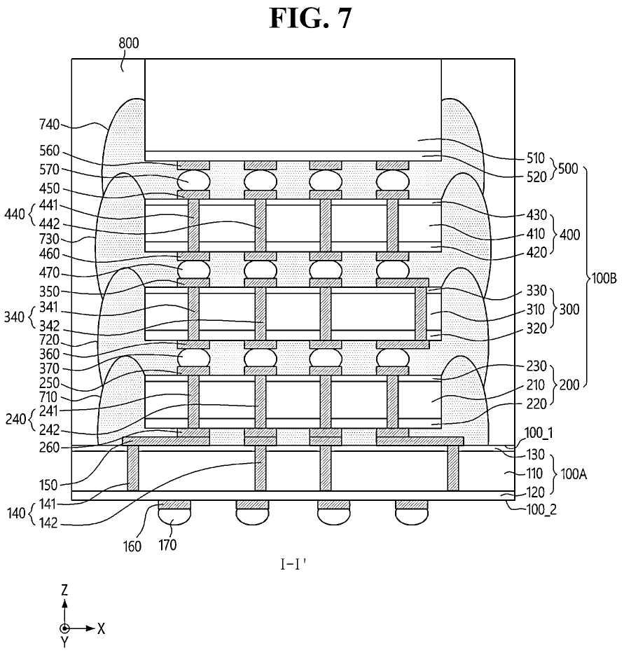

Referring to FIG. 7, the semiconductor package 1000A may not include connection terminals between the base chip 100A and the first semiconductor chip 200. In this case, the upper connection pads 150 on the base chip 100A may be directly bonded to the lower connection pads 260 below the first semiconductor chip 200.

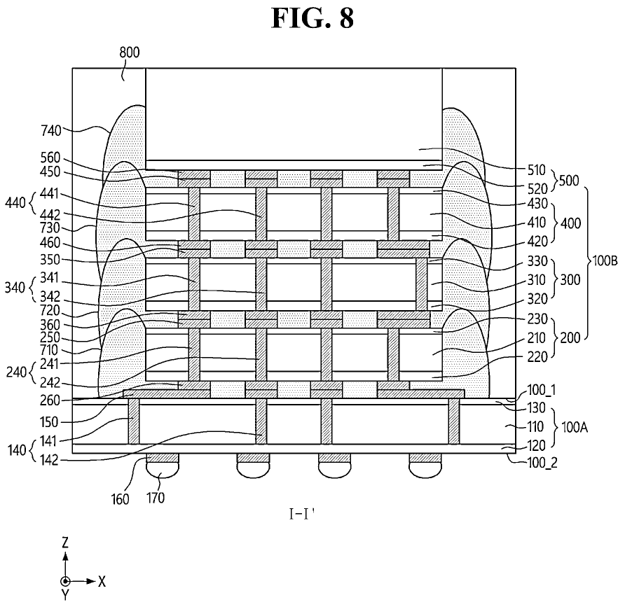

Referring to FIG. 8, the upper connection pads 150 on the base chip 100A may be directly bonded to the lower connection pads 260 below the first semiconductor chip 200.

Also, the first, second, third, and fourth semiconductor chips 200, 300, 400, and 500 may be directly bonded to one another.

In this case, the upper connection pads 250 on the first semiconductor chip 200 may be directly bonded to the lower connection pads 360 below the second semiconductor chip 300. The upper connection pads 350 on the second semiconductor chip 300 may be directly bonded to the lower connection pads 460 below the third semiconductor chip 400. The upper connection pads 450 on the third semiconductor chip 400 may be directly bonded to the lower connection pads 560 below the fourth semiconductor chip 500.

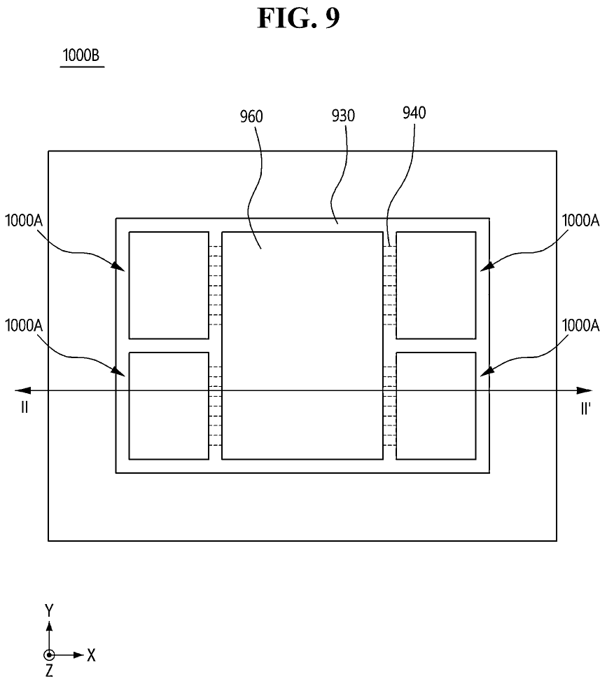

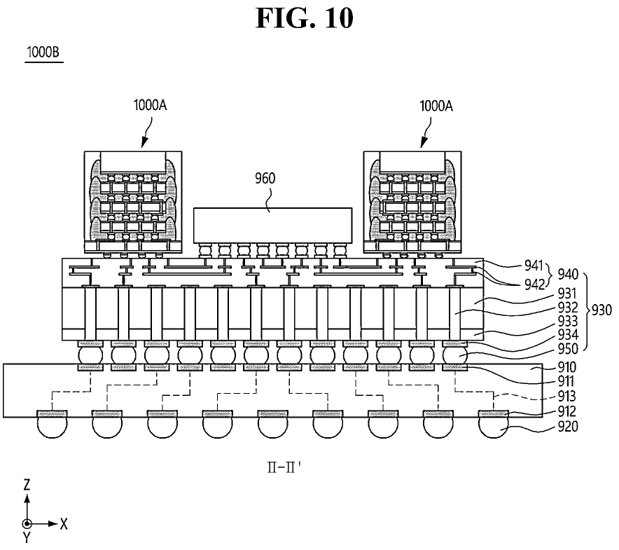

A semiconductor package according to some embodiments of the present disclosure will hereinafter be described with reference to FIGS. 9 and 10.

FIG. 9 is a plan view of a semiconductor package according to some embodiments of the present disclosure. FIG. 10 is a cross-sectional view taken along line II-II′ of FIG. 9 according to some embodiments of the present disclosure. For convenience, the embodiment of FIGS. 9 and 10 will hereinafter be described, focusing mainly on the differences with the embodiments of FIGS. 1 through 8, and repeated descriptions may be omitted.

Referring to FIGS. 9 and 10, a semiconductor package 1000B may include a package substrate 910, an interposer substrate 930, and one or more semiconductor packages 1000A. The semiconductor package 1000B may further include a logic chip (or a processor chip) 960, which is disposed adjacent to the semiconductor packages 1000A. The semiconductor packages 1000A may be the same as the semiconductor package 1000A of FIGS. 1 through 8.

The package substrate 910 may include lower pads 912, which are disposed on the bottom surface of the body of the package substrate 910, and rewiring circuits 913, which electrically connect the lower pads 912 and the upper pads 911. The package substrate 910 may be a support substrate where the interposer substrate 930, the logic chip 960, and the semiconductor packages 1000A are mounted and may also be a substrate for a semiconductor package, including a ceramic substrate, a glass substrate, or a tape wiring substrate.

The body of the package substrate 910 may include different materials depending on the type of the package substrate 910. For example, if the package substrate 910 is a PCB, the package substrate 910 may be a copper-clad laminate or may be a copper-clad laminate with wiring layers additionally stacked on one or both sides thereof.

Solder resist layers may be formed on the bottom and top surfaces of the package substrate 910. The lower pads 912, the upper pads 911, and the rewiring circuits 913 may form electrical paths for connecting the bottom and top surfaces of the package substrate 910.

The lower pads 912, the upper pads 911, and the rewiring circuits 913 may include at least one (or two) of, for example, Cu, Al, Ni, Ag, Au, Pt, Sn, Pb, Ti, chromium (Cr), Pd, In, Zn, carbon (C), and an alloy thereof. The rewiring circuits 913 may include multilayer rewiring layers and vias connecting the multilayer rewiring layers.

The lower pads 912 and outer connection terminals 920, which are connected to the lower pads 912, may be disposed on the bottom surface of the package substrate 910. The outer connection terminals 920 may include Sn, In, Bi, Sb, Cu, Ag, Zn, Pb, and/or an alloy thereof.

The interposer substrate 930 may include a substrate 931, a lower protection layer 933, lower pads 934, a wiring layer 940, bumps 950, and through electrodes 932. The semiconductor packages 1000A and the logic chip 960 may be stacked on the package substrate 910 via the interposer substrate 930. The interposer substrate 930 may electrically connect the semiconductor packages 1000A and the logic chip 960.

The substrate 931 may be formed of one of, for example, Si, an organic material, plastic, and glass. In a case where the substrate 931 is a Si substrate, the interposer substrate 930 may also be referred to as a Si interposer. In a case where the substrate 931 is an organic substrate, the interposer substrate 930 may also be referred to as a panel interposer.

The lower protection layer 933 may be disposed on the bottom surface of the substrate 931, and the lower pads 934 may be disposed on the lower protection layer 933. The lower pads 934 may be connected to the through electrodes 932. The semiconductor packages 1000A and the logic chip 960 may be electrically connected to the package substrate 910 via the bumps 950, which are disposed on the lower pads 934.

The wiring layer 940 may be disposed on the top surface of the substrate 931 and may include an interlayer insulating layer 941 and a single-layer or multilayer wiring structure 942. In a case where the wiring layer 940 has a multilayer structure, wirings from different layers of the wiring layer 940 may be connected to one another via vertical contacts.

The through electrodes 932 may extend from the top surface to the bottom surface of the substrate 931 and may thereby penetrate the substrate 931. The through electrodes 932 may extend into the wiring layer 940 and may thus be electrically connected to the wirings of the wiring layer 940. In a case where the substrate 931 is an Si substrate, the through electrodes 932 may also be referred to as through silicon vias (TSVs). The structure and the material of the through electrodes 932 may be similar to that as described above with reference to FIG. 2. The interposer substrate 930 may not include the through electrodes 932.

The interposer substrate 930 may be used to convert or transmit electrical signals between the package substrate 910 and the semiconductor packages 1000A or between the package substrate 910 and the logic chip 960. Thus, the interposer substrate 930 may not include active or passive devices. In some embodiments, the wiring layer 940 may be disposed below the through electrodes 932. That is, the location of the wiring layer 940 may be relative to the location of the through electrodes 932.

The bumps 950 may be disposed on the bottom surface of the interposer substrate 930 and may be electrically connected to the wirings of the wiring layer 940. The interposer substrate 930 may be stacked on the package substrate 910 via the bumps 950. The bumps 950 may be connected to the lower pads 934 via the wirings of the wiring layer 940 and the through electrodes 932. For example, some of the lower pads 934 that are used for power or ground sources, may be integrated together and may be connected to the bumps 950, and as a result, the number of lower pads 934 may be greater than the number of bumps 950.

The logic chip 960 may include, for example, a central processing unit (CPU), a graphics processor unit (GPU), a field-programmable gate array (FPGA), a digital signal processor (DSP), a cryptographic processor, a microprocessor, a microcontroller, an analog-to-digital converter, or an application-specific integrated circuit (ASIC). The semiconductor package 1000B may also be referred to as a server-oriented or mobile-oriented semiconductor package.

The semiconductor packages 1000A may have a similar characteristic to that of the semiconductor package 1000A of FIGS. 1 through 8. For example, in each of the semiconductor packages 1000A, at least one of a plurality of first base chip through vias 140, which penetrate a base chip 110A, may be offset from one of first semiconductor chip through vias 240, which penetrate a first semiconductor chip 200, second semiconductor chip through vias 340, which penetrate a second semiconductor chip 300, and third semiconductor chip through vias 440, which penetrate a third semiconductor chip 400, in a vertical direction Z.

Also, at least two of the first semiconductor chip through vias 240, the second semiconductor chip through vias 340, and the third semiconductor chip through vias 440 may be offset from each other in the vertical direction Z.

The semiconductor package 1000B may further include an inner sealing member, which covers or at least partially covers the sides and the top surface of each of the logic chip 960 and the semiconductor packages 1000A, on the interposer substrate 930. The semiconductor package 1000B may further include an outer sealing member, which covers or at least partially covers the interposer substrate 930 and the inner sealing member, on the package substrate 910. In some embodiments, the inner and outer sealing members may be formed together and thus may not be able to be distinguished from each other. Also, in some embodiments, the inner sealing member may cover or at least partially cover the top surface of the logic chip 960, but not the top surfaces of the semiconductor packages 1000A.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A semiconductor package comprising:
a base chip comprising a top surface extending in a first horizontal direction and a second horizontal direction intersecting the first horizontal direction;
a semiconductor chip stack comprising a first semiconductor chip and a second semiconductor chip which are sequentially stacked on the base chip in a vertical direction and are aligned on respective sides in the vertical direction;
first through vias penetrating the base chip and spaced apart from each other in the first horizontal direction;
second through vias penetrating the first semiconductor chip and spaced apart from each other in the first horizontal direction;
third through vias penetrating the second semiconductor chip and spaced apart from each other in the first horizontal direction; and
first connection pads contacting the first through vias;
second connection pads contacting the second through vias; and
third connection pads contacting the third through vias,
wherein at least one of the first through vias is offset from at least one of the second through vias in the vertical direction,
wherein at least one of the first through vias is aligned with at least one of the second through vias in the vertical direction,
wherein at least one of the second through vias is offset from at least one of the third through vias in the vertical direction, and
wherein at least one of the second through vias is aligned with at least one of the third through vias in the vertical direction.

2. The semiconductor package of claim 1, wherein a first distance, in the first horizontal direction, between two adjacent first through vias of the first through vias is different from a second distance, in the first horizontal direction, between two adjacent second through vias of the second through vias.

3. The semiconductor package of claim 1, wherein a first distance, in the first horizontal direction, between two adjacent second through vias of the second through vias is different from a second distance, in the first horizontal direction, between two adjacent third through vias of the third through vias.

4. The semiconductor package of claim 1, wherein the first through vias comprise (1_1)-th through vias and (1_2)-th through vias which are adjacent to the (1_1)-th through vias in the first horizontal direction,
wherein the second through vias comprise (2_1)-th through vias and (2_2)-th through vias which are adjacent to the (2_1)-th through vias in the first horizontal direction,
wherein the (1_1)-th through vias and the (2_1)-th through vias are aligned in the vertical direction, and
wherein the (1_2)-th through vias and the (2_2)-th through vias are aligned in the vertical direction.

5. The semiconductor package of claim 1, wherein the first connection pads comprise (1_1)-th connection pads and (1_2)-th connection pads which are adjacent to the (1_1)-th connection pads in the first horizontal direction,
wherein the second connection pads comprise (2_1)-th connection pads and (2_2)-th connection pads which are adjacent to the (2_1)-th connection pads in the first horizontal direction,
wherein the third connection pads comprise (3_1)-th connection pads and (3_2)-th connection pads which are adjacent to the (3_1)-th connection pads in the first horizontal direction,
wherein a first length, in the first horizontal direction, of the (1_1)-th connection pads is different from a second length, in the first horizontal direction, of the (1_2)-th connection pads, and
wherein a third length, in the first horizontal direction, of the (2_1)-th connection pads is different from a fourth length, in the first horizontal direction, of the (2_2)-th connection pads.

6. The semiconductor package of claim 1, further comprising:
first solder bumps between the base chip and the first semiconductor chip; and
second solder bumps between the first semiconductor chip and the second semiconductor chip,
wherein a first distance, in the first horizontal direction, between the first solder bumps is different from a second distance, in the first horizontal direction, between the second solder bumps.

7. The semiconductor package of claim 1, wherein the first connection pads are directly bonded to the second connection pads.

8. The semiconductor package of claim 1, further comprising:
a mold layer at least partially covering the base chip, the first semiconductor chip, and the second semiconductor chip, on the top surface of the base chip.

9. The semiconductor package of claim 8, further comprising:
a first underfill material layer between the mold layer and the first semiconductor chip; and
a second underfill material layer between the first semiconductor chip and the second semiconductor chip,
wherein the first underfill material layer and the second underfill material layer are non-conductive.

10. A semiconductor package comprising:
a base chip comprising a top surface extending in a first horizontal direction a second horizontal direction intersecting the first horizontal direction;
a semiconductor chip stack comprising semiconductor chips, which are sequentially stacked on the base chip in a vertical direction and are aligned on respective sides in the vertical direction;
first through vias extending into the base chip and spaced apart from each other in the first horizontal direction;
second through vias extending into the semiconductor chip stack and spaced apart from each other in the first horizontal direction;
first connection pads contacting the first through vias; and
second connection pads contacting the second through vias,
wherein a first distance, in the first horizontal direction, between the first through vias is different from a second distance, in the first horizontal direction, between the second through vias, and
wherein a third distance, in the first horizontal direction, between the first connection pads is different from a fourth distance, in the first horizontal direction, between the second connection pads.

11. The semiconductor package of claim 10, wherein the semiconductor chips comprises a first semiconductor chip, a second semiconductor chip, and a third semiconductor chip which are sequentially stacked on the top surface of the base chip,
wherein the second through vias comprises (2_1)-th through vias which penetrate the first semiconductor chip, and (2_2)-th through vias which penetrate the second semiconductor chip, and
wherein a fifth distance in the first horizontal direction between the (2_1)-th through vias is different from a sixth distance in the first horizontal direction between the (2_2)-th through vias.

12. The semiconductor package of claim 11, further comprising:
first solder bumps between the base chip and the first semiconductor chip; and
second solder bumps between the first semiconductor chip and the second semiconductor chip,
wherein a seventh distance, in the first horizontal direction, between the first solder bumps is different from an eighth distance, in the first horizontal direction, between the second solder bumps.

13. The semiconductor package of claim 12, further comprising:
third solder bumps between the second semiconductor chip and the third semiconductor chip,
wherein a ninth distance between the third solder bumps is different from a tenth distance between the second solder bumps.

14. The semiconductor package of claim 10, wherein the first through vias are positioned within a horizontal width of the semiconductor chip stack.

15. The semiconductor package of claim 10, wherein the base chip and the semiconductor chip stack are electrically connected through the first through vias and the second through vias.

16. A semiconductor package comprising:
a base chip comprising top surface extending in a first horizontal direction and a second horizontal direction intersecting the first horizontal direction;
a semiconductor chip stack comprising a first semiconductor chip and a second semiconductor chip which are sequentially stacked on the base chip in a vertical direction and are aligned on respective sides in the vertical direction;
first through vias penetrating the base chip and spaced apart from each other in the first horizontal direction;
second through vias penetrating the first semiconductor chip and spaced apart from each other in the first horizontal direction;
third through vias penetrating the second semiconductor chip and spaced apart from each other in the first horizontal direction;
a connection structure comprising:
first connection pads between the base chip and the first semiconductor chip; and
second connection pads between the first semiconductor chip and the second semiconductor chip;
a mold layer at least partially covering the semiconductor chip stack on the top surface of the base chip; and
underfill material layers between the mold layer and between the first semiconductor chip and the second semiconductor chip,
wherein at least one of the first through vias is offset from at least one of the second through vias in the vertical direction, and
wherein at least one of the second through vias is offset from at least one of the third through vias in the vertical direction.

17. The semiconductor package of claim 16, wherein a first distance, in the first horizontal direction, between the first through vias is different from a second distance, in the first horizontal direction, between the second through vias.

18. The semiconductor package of claim 16, wherein a third distance, in the first horizontal direction, between the second through vias is different from a fourth distance, in the first horizontal direction, between the third through vias.

19. The semiconductor package of claim 16, wherein the connection structure further comprises:
first solder bumps between the base chip and the first semiconductor chip; and
second solder bumps between the first semiconductor chip and the second semiconductor chip, and
wherein a fifth distance, in the first horizontal direction, between the first solder bumps is different from a sixth distance, in the first horizontal direction, between the second solder bumps.

20. The semiconductor package of claim 16, wherein the first connection pads are directly bonded to each another, and
wherein the second connection pads are directly bonded to each another.
